(19) United States
(12) Patent Application Publication
(10) Pub. No.: US 2012/0217497 A1
(43) Pub. Date: Aug. 30, 2012

(54) MANUFACTURING METHOD FOR SEMICONDUCTOR DEVICE, MANUFACTURING APPARATUS FOR SEMICONDUCTOR DEVICE, AND SEMICONDUCTOR DEVICE

(75) Inventors: Fumito Shoji, Ishikawa (JP); Noriteru Yamada, Oita (JP)

(73) Assignee: KABUSHIKI KAISHA TOSHIBA, Tokyo (JP)

(21) Appl. No.: 13/351,280

(22) Filed: Jan. 17, 2012

(30) Foreign Application Priority Data
Feb. 28, 2011 (JP) 2011-042137

(51) Int. Cl. H01L 23/58; B05C 11/00; H01L 21/66

(52) U.S. Cl. 257/48; 438/10; 118/708; 257/E23.002; 257/E21.531

(57) ABSTRACT

According to one embodiment, a manufacturing method for a semiconductor device includes: forming a test pattern with a metal film embedded therein through a plating process; detecting a characteristic of the test pattern; and adjusting a condition for the plating process based on the detected characteristic of the test pattern. The test pattern is formed over three or more wiring layers and includes a stacked via in an intermediate layer.

### CROSS-REFERENCE TO RELATED APPLICATIONS

This application is based upon and claims the benefit of priority of Japanese Patent Application No. 2011-42137, filed on Feb. 28, 2011, the entire contents of which are incorporated herein by reference.

### FIELD

Embodiments described herein relate generally to a manufacturing method for a semiconductor device, a manufacturing method for a semiconductor device, and a semiconductor device.

### BACKGROUND

In recent years, as a manufacturing method for a semiconductor device, a method of forming wires and the like with a damascene method is used. The damascene method is, for example, a method of forming wiring grooves in an interlayer insulating film and, after embedding metal films such as copper (Cu) films in the wiring grooves through a plating process, removing the excess metal films through chemical mechanical polishing (CMP) to thereby form wires.

In such a damascene method, to keep film formation quality, the density of inorganic and organic components contained in a plating solution is managed to be fixed component density. However, embedding properties of the metal films are deteriorated because of factors other than the managed component density.

### BRIEF DESCRIPTION OF THE DRAWINGS

FIGS. 1A and 1B are diagrams for explaining a manufacturing method for a semiconductor device according to an embodiment;

FIG. 2 is a schematic diagram of the configuration of a test pattern of the semiconductor device according to the embodiment;

FIG. 3A is a sectional view taken along line A-A shown in FIG. 2;

FIG. 3B is a sectional view taken along line B-B shown in FIG. 2;

FIGS. 4A, 4B, 5A, and 5B are diagrams for explaining a method of forming the test pattern according to the embodiment;

FIG. 6 is a diagram of the configuration of a manufacturing apparatus according to the embodiment;

FIG. 7 is a diagram of the configuration of a plating apparatus according to the embodiment;

FIG. 8 is a diagram of the configuration of a detecting apparatus according to the embodiment; and

FIG. 9 is a flowchart for explaining a flow of processing of the manufacturing apparatus according to the embodiment.

### DETAILED DESCRIPTION

In general, according to one embodiment, a manufacturing method for a semiconductor device includes: forming a test pattern with a metal film embedded therein through a plating process; detecting a characteristic of the test pattern; and adjusting a condition for the plating process based on the detected characteristic of the test pattern. The test pattern is formed over three or more wiring layers and has a stacked via in an intermediate layer.

Exemplary embodiments of a manufacturing method for a semiconductor device, a manufacturing apparatus for a semiconductor device, and a semiconductor device will be explained below in detail with reference to the accompanying drawings. The present invention is not limited to the following embodiments. In the following explanation, the manufacturing method for a semiconductor device is simply referred to as “manufacturing method” and the manufacturing apparatus for a semiconductor device is simply referred to as “manufacturing apparatus”.

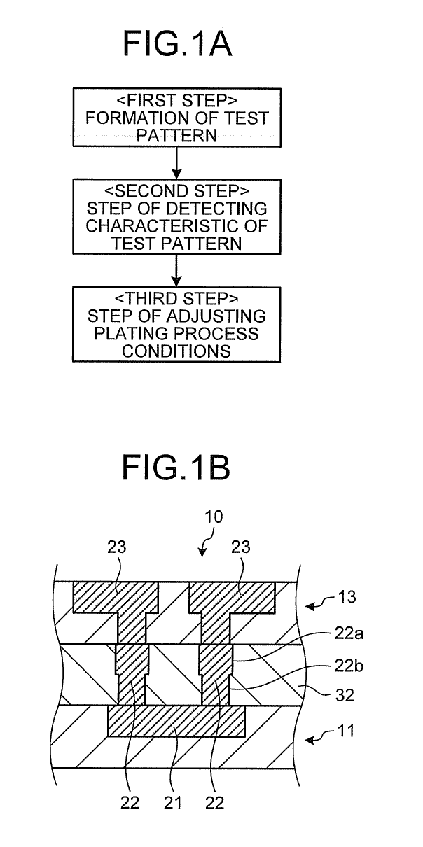

First, a manufacturing method according to an embodiment is explained with reference to FIGS. 1A and 1B. FIGS. 1A and 1B are diagrams for explaining the manufacturing method according to the embodiment.

As shown in FIG. 1A, the manufacturing method according to this embodiment includes first to third steps. Plating process conditions are appropriately adjusted according to these steps.

The first step is a step of forming a test pattern on a substrate (e.g., a silicon wafer). The test pattern is a pattern connected over three or more wiring layers through a via and having a stacked via in an intermediate layer. For example, as shown in FIG. 18, a pattern of a three-layer structure having stacked vias 22 is formed as a test pattern 10 in an intermediate layer between a first wiring layer 11 in which a wire 21 is formed and a third wiring layer 13 in which wires 23 are formed.

The test pattern 10 is simultaneously formed when wires in a device area are formed by the damascene method. The stacked vias 22 are formed by a dual damascene method for forming wiring grooves 22a and connection holes 22b in an interlayer insulating film 32 and embedding metal plating films in the wiring grooves 22a and the connection holes 22b at a time.

Examples of the metal plating films include copper (Cu) plating films and alloy plating films containing Cu. In the following explanation, the Cu plating films are explained as an example. In the wiring grooves 22a and the connection holes 22b, Cu plating films are formed after barrier metal layers, seed layers, and the like are formed by a sputtering method or the like. In an example shown in FIG. 1B, layers such as the barrier metal layers and the seed layers are omitted.

A void tends to occur in the stacked vias 22 because the stacked vias 22 have a structure with a high aspect ratio. Therefore, it is possible to highly accurately perform detection of embedding properties and film formation characteristics of the Cu plating films using the pattern 10 having the stacked vias 22.

The second step is a step of detecting a characteristic of the test pattern 10. The characteristic to be detected is, for example, the electric resistance of the test pattern 10. The electric resistance is detected based on, for example, a value of a voltage generated by feeding a predetermined electric current to the test pattern 10.

The stacked vias 22 included in the test pattern 10 has a high aspect ratio as explained above. Therefore, the electric resistance sensitively fluctuates in response to the deterioration in the embedding properties and the film formation characteristics of the Cu plating films. Therefore, it is possible to accurately detect embedded states and film formation states of the Cu plating films with respect to the stacked vias 22 by detecting the electric resistance of the test pattern 10.

The third step is a step of adjusting plating process characteristics based on the characteristic of the test pattern 10 detected in the second step. The plating process characteristics adjusted in this way are fed back to the Cu plating film formation process in the first step performed when the stacked vias 22 of the test pattern 10 are formed.

In this way, in the manufacturing method according to this embodiment, a test pattern having stacked vias in an intermediate layer is formed by the damascene method and Cu plating process conditions are adjusted based on a characteristic of the test pattern. Therefore, it is possible to stabilize embedding properties and film formation characteristics of the Cu plating films.

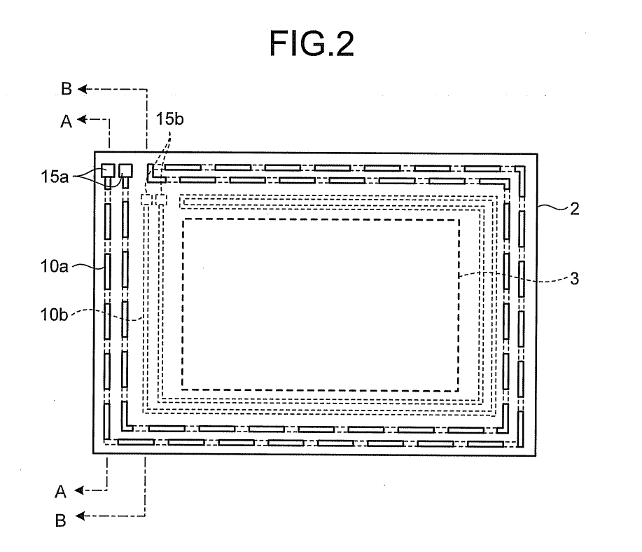

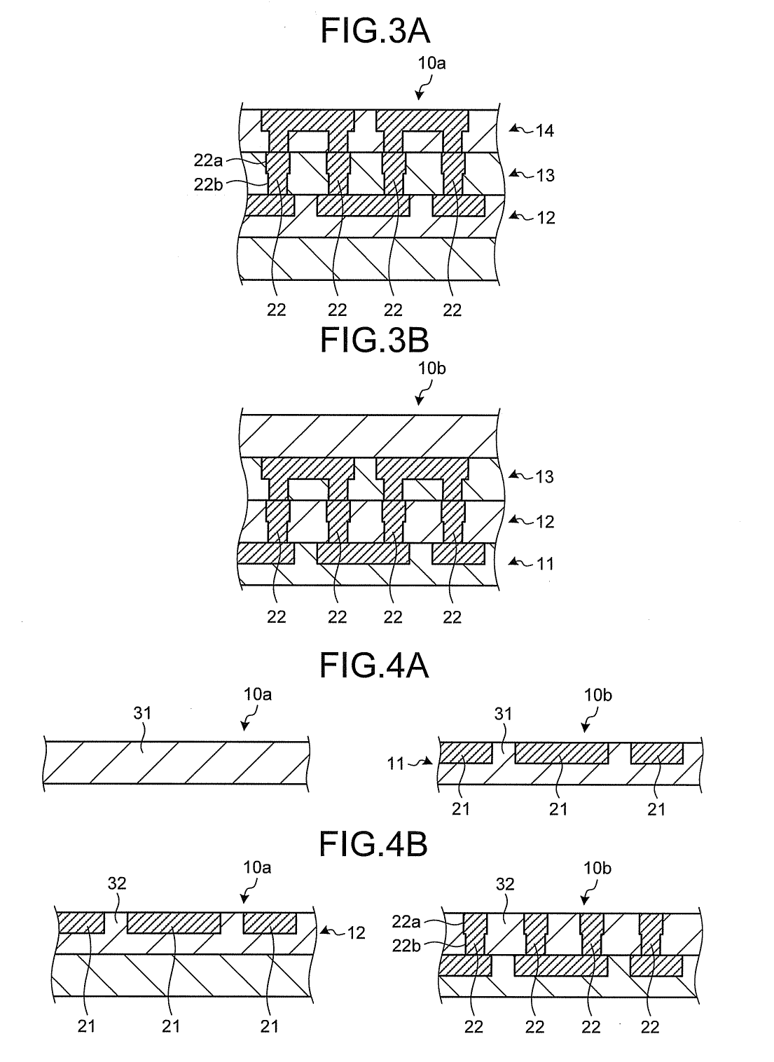

The manufacturing method according to this embodiment is explained more in detail with reference to the drawings. First, a test pattern is specifically explained. FIG. 2 is a schematic diagram of the configuration of a test pattern of the semiconductor device according to this embodiment. FIG. 3A is a sectional view taken along line A-A shown in FIG. 2. FIG. 3B is a sectional view taken along line B-B shown in FIG. 2.

As shown in FIG. 2, in each semiconductor chip area 2 formed on a substrate such as a silicon wafer, two test patterns 10a and 10b are formed as test patterns 10. In this example, the number of test patterns formed in the semiconductor chip area 2 is two. However, the number of test patterns 10 formed in the semiconductor chip area 2 can be one or three or more. By forming the test patterns 10 by a number corresponding to the number of wiring layers in which embedded states and film formation states of Cu plating films are detected, it is possible to detect the embedded states and the film formation states of the Cu plating films of the wiring layers.

The test patterns 10a and 10b are arranged to surround the outer periphery of the device area 3 where a semiconductor element and the like are formed. Electrode pads 15a and 15b are formed at both ends of the test patterns 10a and 10b. The test patterns 10a and 10b are arranged near the outer periphery of the semiconductor chip area 2 and formed to be turned back in intermediate portions the test patterns 10a and 10b. Therefore, the pattern lengths of the test patterns 10a and 10b can be increased.

Therefore, a large number of stacked vias 22 can be included in the test patterns 10a and 10b. The fluctuation in electric resistance responding to the deterioration in the embedding properties and the film formation characteristics of the Cu plating films can be increased. The embedding properties include, for example, a bottom-up amount and a loss of a wiring surface. The film formation characteristics include, for example, an amount of impurities contained in the plating films and an over plating amount in a wiring section having high density.

As shown in FIG. 3A, the test pattern 10a is a pattern that meanders among three wiring layers. The test pattern 10a is formed in a meandering shape in sectional view from a second wiring layer 12 to a fourth wiring layer 14. The test pattern 10a includes a plurality of stacked vias 22 in an intermediate layer between the second wiring layer 12 and the fourth wiring layer 14. The stacked vias 22 has a structure in which the diameter of the wiring grooves 22a is substantially the same as the diameter of the connection holes 22b and an aspect ratio is high.

The test pattern 10a is simultaneously formed when wires are formed in the device area 3 by the damascene method. The stacked vias 22 of the test pattern 10a are formed by the dual damascene method for, after forming barrier metal layers, seed layers, and the like in the wiring grooves 22a and the connection holes 22b, embedding Cu plating films in the wiring grooves 22a and the connection holes 22b at a time.

As shown in FIG. 3B, the test pattern 10b is a pattern that meanders among three wiring layers. The test pattern 10b is formed in a meandering shape in sectional view from the first wiring layer 11 to the third wiring layer 13. The test pattern 10b includes a plurality of stacked vias 22 in an intermediate layer between the first wiring layer 11 and the third wiring layer 13. The test pattern 10b has a configuration same as that of the test pattern 10a except the formed wiring layers and is formed by the damascene method.

The test pattern 10a and the test pattern 10b are formed in the intermediate layers in which the stacked vias 22 are different from each other. This makes it possible to detect embedded states and film formation states of Cu plating films in layers different from each other. Specifically, in the test pattern 10a, it is possible to detect embedded states and film formation states of Cu plating films formed when wires are formed in the third wiring layer 13. In the test pattern 10b, it is possible to detect embedded states and film formation states of Cu plating films formed when wires are formed in the second wiring layer 12.

Instead of forming the test patterns 10a and 10b in all semiconductor chip areas 2, the test patterns 10a and 10b can be formed only in a part of the semiconductor chip areas 2. For example, the test patterns 10a and 10b can be formed in the semiconductor chip area 2 in the center part of the substrate and the semiconductor chip area 2 in the peripheral part of the substrate among a plurality of semiconductor chip areas 2 formed on the substrate.

The pattern of the three-layer structure is explained as the test pattern 10 above. However, the test pattern 10 only has to be a pattern including a stacked via structure in an intermediate layer. The test pattern 10 can be formed over four or more layers. For example, a pattern having a stacked via structure of two or more stages can be formed as the test pattern 10. Consequently, it is possible to detect, at a time, embedding of Cu plating films by a plurality of plating steps and simplify the detecting step.

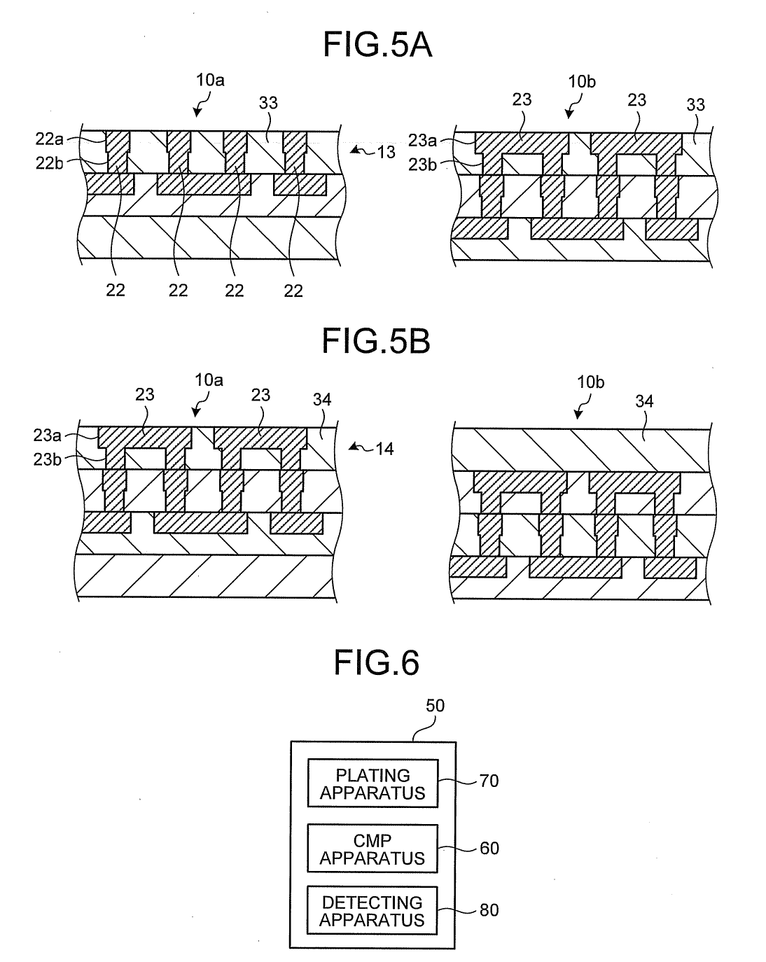

A method of forming the test patterns 10a and 10b is explained with reference to FIGS. 4A, 4B, 5A, and 5B. FIGS. 4A, 4B, 5A, and 5B are diagrams for explaining a procedure of the method of forming the test patterns 10a and 10b.

As in FIG. 10B, in connection holes and wiring grooves formed in an interlayer insulating film, Cu plating films are embedded after metal thin films such as barrier metal layers and seed layers forming a substrate are formed. However, in FIGS. 4A, 4B, 5A, and 5B, the metal thin films forming the substrate are omitted. As the barrier metal layers, for example, tantalum (Ta) is used. As the seed layers, for example, copper (Cu) is used.

As shown in FIG. 4A, in a formation area of the test pattern 10b, wires 21 are formed in an interlayer insulating film 31. Specifically, after wiring grooves are formed in the interlayer insulating film 31 and barrier metal layers, seed layers, and the like are formed in the wiring grooves, a Cu film is deposited on a substrate surface including the wiring grooves by a plating process. The substrate surface is polished by the chemical mechanical polishing (CMP) method to remove the Cu film and the like deposited on the substrate surface other than the wiring grooves and form the wires 21.

Subsequently, as shown in FIG. 4B, the stacked vias 22 are formed in the interlayer insulating film 32 in the formation area of the test pattern 10b. Specifically, after the interlayer insulating film 32 is formed, the wiring grooves 22a and the connection holes 22b are formed and barrier metal layers and seed layers are formed in the wiring grooves 22a and the connection holes 22b. After a Cu film is deposited on a substrate surface including the wiring grooves 22a and the connection holes 22b by the plating process, the substrate surface is polished by the CMP method to remove the Cu film and the like deposited on the substrate surface other than the wiring grooves 22a and the connection holes 22b. On the other hand, On the other hand, in a formation area of the test pattern 10a, the wires 21 are formed in the interlayer insulating film 32 by a method same as the method of forming the wires 21 of the test pattern 10b explained above.

As shown in FIG. 5A, the wires 23 are formed in an interlayer insulating film 33 in the formation area of the test pattern 10b. Specifically, after the interlayer insulating film 33 is formed, the wiring grooves 23a and the connection holes 23b are formed and barrier metal layers and seed layers are formed in the wiring grooves 23a and the connection holes 23b. After a Cu film is deposited on a substrate surface including the wiring grooves 23a and the connection holes 23b by the plating process, the substrate surface is polished by the CMP method to remove the Cu film and the like deposited on the substrate surface other than the wiring grooves 23a and the connection holes 23b and form the wires 23. Consequently, the test pattern 10b is formed. On the other hand, in the formation area of the test pattern 10a, the stacked vias 22 are formed in the interlayer insulating film 33 by a method same as the method of forming the stacked vias 22 of the test pattern 10b.

As shown in FIG. 5B, an interlayer insulating film 34 is formed in the formation area of the test pattern 10b. On the other hand, in the formation area of the test pattern 10a, the wires 23 are formed in the interlayer insulating film 34 by a method same as the method of forming the wires 23 of the test pattern 10b.

As the interlayer insulating films 31 to 34, for example, a laminated film of a silicon oxide film and a silicon nitride film is used. However, the interlayer insulating films 31 to 34 are not limited to this. The procedure for forming the test patterns 10a and 10b explained with reference to FIGS. 4A, 4B, 5A, and 5B is only an example. The test patterns 10a and 10b can be formed by other methods as long as the test patterns 10a and 10b are formed by embedding of metal films such as Cu films by the plating process.

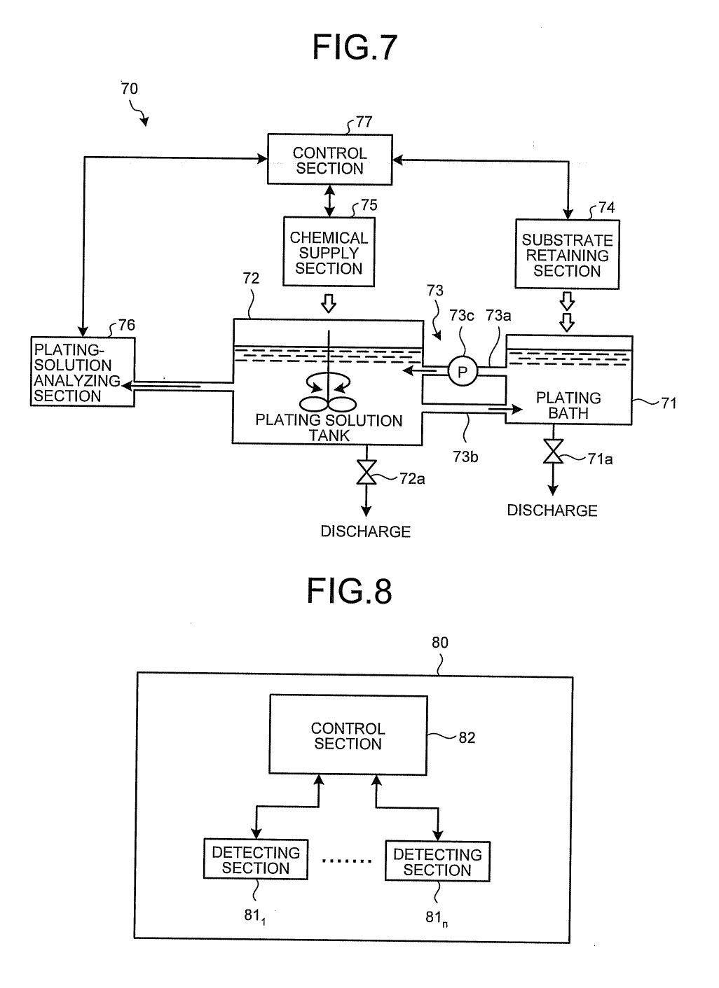

The manufacturing apparatus according to the embodiment is specifically explained with reference to the drawings. FIG. 6 is a diagram of the configuration of the manufacturing apparatus according to the embodiment. FIG. 7 is a diagram of the configuration of a plating apparatus according to the embodiment. FIG. 8 is a diagram of the configuration of a detecting apparatus according to the embodiment.

As shown in FIG. 6, a manufacturing apparatus 50 according to the embodiment includes a CMP apparatus 60, a plating apparatus 70, and a detecting apparatus 80. Such a manufacturing apparatus 50 functions as, for example, a forming section configured to form the test patterns 10a and 10b on the substrate, a detecting section configured to detect characteristics of the test patterns 10a and 10b, and an adjusting section configured to adjust plating process conditions based on the characteristics of the test patterns 10a and 10b. Although not shown in the figure, the manufacturing apparatus 50 also includes, for example, an apparatus that forms an interlayer insulating film in the semiconductor chip area 2, an apparatus that forms wiring grooves and connection holes in the interlayer insulating film, and an apparatus that performs cleaning after CMP by the CMP apparatus 60.

The CMP apparatus 60 polishes, with the CMP method, a substrate surface subjected to plating film formation by the plating apparatus 70 and forms wires in the semiconductor chip area 2.

As shown in FIG. 7, the plating apparatus 70 includes a plating bath 71, a plating solution tank 72, a plating solution circulation line 73, a substrate retaining section 74, a chemical supply section 75, a plating-solution analyzing section 76, and a control section 77.

The plating bath 71 can store a plating solution in an amount sufficient for immersing a substrate on which a film is formed (hereinafter referred to as “film formation substrate”). The film formation substrate is brought into contact with an electric contact and energized to perform a Cu plating process. A drain 71a including a valve for discharging the plating solution is provided in the plating bath 71. A drain 72a including a valve for discharging a stored plating solution is provided in the plating solution tank 72. The plating bath 71 can be a plating bath of a spray type for spraying the plating solution to the film formation substrate and perform the plating process.

The plating solution circulation line 73 circulates the plating solution between the plating bath 71 and the plating solution tank 72. The plating solution circulation line 73 includes a first pipe 73a for feeding the plating solution from the plating bath 71 to the plating solution tank 72, a second pipe 73b for feeding the plating solution from the plating solution tank 72 to the plating bath 71, and a solution feeding pump 73c provided in the first pipe 73a.

The substrate retaining section 74 has a structure for rotatably retaining the film formation substrate and moving the film formation substrate into the plating bath 71. The substrate retaining section 74 is controlled according to a command signal from the control section 77. For example, the substrate retaining section 74 rotates the film formation substrate at the number of revolutions and in a rotating direction conforming to the command signal from the control section 77.

The chemical supply section 75 supplies, according to a command signal from the control section 77, for example, a new plating solution adjusted to a predetermined composition, a chemical necessary for supplementing organic components and inorganic components, pure water for diluting the plating solution to the plating solution tank 72. Examples of the chemical include a copper sulfate basic solution serving as a basic solution for the plating solution and an organic component added to the plating solution to facilitate plating film growth in wiring grooves during plating film formation.

The plating-solution analyzing section 76 periodically analyzes, for example, with a titration method, the component density of a predetermined component forming the plating solution and notifies the control section 77 of an analysis result. In an example shown in FIG. 7, the plating-solution analyzing section 76 has a structure for sampling the plating solution from the plating solution tank 72. However, the plating solution can be sampled from the plating bath 71 or the plating solution circulation line 73.

The control section 77 adjusts the plating solution based on the analysis result by the plating-solution analyzing section 76 such that the component density of the predetermined component included in the plating solution reaches target density. Specifically, concerning a component having density lower than target density, the control section 77 supplies a chemical corresponding to the component from the chemical supply section 75. Conversely, when the density is higher than the target density, the control section 77 discharges the plating solution and supplies water, the copper sulfate basic solution, or the like.

When the control section 77 discharges the plating solution and supplies water, the copper sulfate basic solution, or the like, the densities of other components simultaneously fluctuate. Therefore, the control section 77 carries out plating film formation after performing measurement of density again and performing plating solution adjustment such that the densities of all components including inorganic components and organic components reach target densities.

To embed Cu films in wiring grooves and connection holes without causing a void and the like, it is desirable to properly setting the growth balance of the Cu films from the bottoms or sidewalls of the wiring grooves and the connection holes. The growth balance of the Cu films is affected by not only the plating solution density but also other factors.

For example, as a factor affecting the growth balance of the Cu films, there is the density of an organic byproduct generated during a plating process. The organic byproduct is a component decomposed and derived from an organic component in the plating solution. As another factor affecting the growth balance of the Cu films, there is a local temperature rise of the substrate and the plating solution that occurs during the plating process. The temperature rise is caused by, for example, heat generation that occurs when an electric contact and the film formation substrate are energized during the plating process.

As explained above, the growth balance of the Cu films is affected by not only the component density in the plating solution but also other factors. Therefore, even when adjustment of the plating solution is performed, embedding properties and film formation characteristics of the Cu plating films such as a bottom-up amount and a loss of a wiring surface could be deteriorated. Therefore, for example, a void could occur.

Therefore, the manufacturing apparatus 50 forms the test pattern 10 with which embedded states and film formation states of the Cu plating films can be accurately detected and adjusts plating process conditions according to a characteristic of the test pattern 10.

Specifically, the control section 77 of the plating apparatus 70 acquires information concerning the characteristic of the test pattern detected by the detecting apparatus 80. Based on the characteristic of the test pattern 10, the control section 77 functions as adjusting means for adjusting, for example, a current value during plating film formation, the number of revolutions of the substrate, the temperature of the plating solution in the plating bath 71, a flow rate of the plating solution, a discharge amount and a supply amount of the plating solution, and a standby time before a plating process for the substrate. The standby time before the plating process for the substrate is, for example, time until a plating process for the next substrate is performed after the immediately preceding plating process for the substrate.

When the embedded states and the film formation states of the Cu plating films are poor, for example, the control section 77 increases the current value during the plating film formation and reducing the number of revolutions of the substrate to improve embedding properties of the Cu plating films. The control section 77 can increase at least any one of the temperature of the plating solution, the flow rate of the plating solution, and the discharge amount and the supply amount of the plating solution.

In this way, the control section 77 changes, according to the detected embedded state and film formation state of the Cu plating film, one or more parameters among the current value during the plating film formation, the number of revolutions of the substrate, the temperature of the plating solution in the plating bath 71, the flow rate of the plating solution, the discharge amount and the supply amount of the plating solution, and the standby time before the plating process for the substrate to adjust plating process conditions.

When the control section 77 adjusts the current value during the plating film formation, for example, the control section 77 controls the plating bath 71 to adjust a plating voltage. When the control section 77 adjusts the number of revolutions of the substrate, the control section 77 adjusts a command signal to the substrate retaining section 74. When the control section 77 adjusts the temperature of the plating solution in the plating bath 71, the flow rate of the plating solution, and the discharge amount and the supply amount of the plating solution, the control section 77 controls, for example, the plating bath 71, the drain 71a, the solution feeding pump 73c, and the like.

The detecting apparatus 80 that detects characteristics of the test patterns 10 is explained. FIG. 8 is a diagram of the configuration of the detecting apparatus 80.

As shown in FIG. 8, the detecting apparatus 80 includes a plurality of detecting sections 81₁ to 81ₙ and a control section 82. The detecting apparatus 80 functions as a detecting section configured to detect characteristics of the test patterns 10 formed in the semiconductor chip areas 2.

The detecting sections 81₁ to 81ₙ are provided to correspond to the semiconductor chip areas 2. The detecting sections 81₁ to 81ₙ detect the electric resistances of the test patterns 10 according to a command signal from the control section 82. For example, when the detecting sections 81₁ to 81ₙ detect the electric resistance of the test pattern 10a shown in FIG. 2, the detecting sections 81₁ to 81ₙ feed a constant current between the electrodes 15a at both the ends of the test pattern 10a and detect a voltage generated between the electrodes 15a to detect the electric resistance of the test pattern 10a.

The control section 82 determines, from the electric resistances of the test patterns 10 acquired from the detecting sections 81₁ to 81ₙ, embedded states and film formation states of the Cu plating films in the semiconductor chip areas 2. For example, the control section 82 determines the semiconductor ship area 2, in which the electric resistance of the test pattern 10 is outside a normal range, as a defective chip and detects the number and the distribution of defective chips on the substrate. The control section 82 discriminates, for example, a fluctuation amount of resistance between substrates.

The detecting sections 81₁ to 81ₙ include image pickup sections and image analyzing sections. The detecting sections 81₁ to 81ₙ analyze, with the image analyzing sections, surface images of the stacked vias 22 picked up by the image pickup sections and determine whether the surface of the stacked vias 22 are lost.

For example, it is assumed that a CMP process for forming wires of the third wiring layer 13 is performed by the CMP apparatus 60 and the test pattern 10a shown in FIG. 5A is formed. In this case, the detecting sections 81₁ to 81ₙ pick up images of the surfaces of the stacked vias 22 after the CMP with the image pickup sections and analyze the picked-up images with the image analyzing sections to determine a loss of the surfaces of the stacked vias 22.

The control section 82 notifies the plating apparatus 70 of, as characteristics of the test patterns 10, the electric resistances of the test patterns 10 and information based on the electric resistances and information concerning losses of the surfaces of the stacked vias 22. The control section 77 of the plating apparatus 70 adjust plating process conditions based on the characteristics of the test patterns 10 detected by the detecting apparatus 80. For example, when the characteristics of the test patterns 10 detected by the detecting apparatus 80 are in an abnormal range, the control section 77 adjusts the plating process conditions.

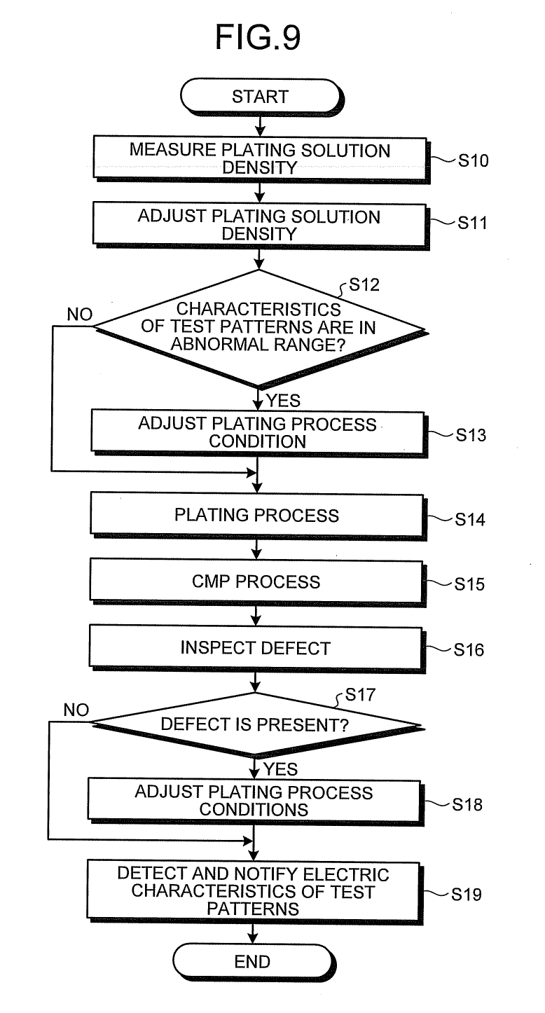

An example of a flow of processing by the manufacturing apparatus 50 configured as explained above is explained with reference to FIG. 9. FIG. 9 is a flowchart for explaining an example of the flow of the processing by the manufacturing apparatus 50. The processing by the manufacturing apparatus 50 includes various steps. However, to clarify the explanation, processing concerning the CMP apparatus 60, the plating apparatus 70, and the detecting apparatus 80 is mainly explained.

The various steps include, for example, a step of forming the interlayer insulating film 33, the wiring grooves 22a, and the connection holes 22b, a step of forming barrier metal layers, seed layers, and the like in the wiring grooves 22a and the connection grooves 22b with the sputtering method or the like, and a step of performing cleaning after the CMP.

As shown in FIG. 9, the plating-solution analyzing section 76 of the plating apparatus 70 periodically analyzes, for example, with the titration method, component density of a predetermined component forming the plating solution and notifies the control section 77 of an analysis result (step S10). The control section 77 adjusts the plating solution based on the analysis result by the plating-solution analyzing section 76 such that the component density of the predetermined component included in the plating solution reaches target density (step S11).

Subsequently, the control section 77 determines whether characteristics of the test patterns 10 are in the abnormal range (step S12). Specifically, the control section 77 determines whether characteristics of the test patterns 10 of another substrate detected in the next wiring step are in the abnormal range. For example, when the third wiring layer 13 is formed in a plating process explained later, the control section 77 determines whether an electric characteristic of the test pattern 10a detected on another substrate in which the fourth wiring layer 14 is formed is in the abnormal range.

When the control section 77 determines that the characteristics of the test patterns 10 are in the abnormal range (Yes at step S12), the control section 77 adjusts plating process conditions, which are conditions for a plating process explained later, based on the acquired characteristics of the test patterns 10 (step S13). Examples of the plating process conditions include a current value during plating film formation, the number of revolutions of the substrate, the temperature of the plating solution in the plating bath 71, a flow rate of the plating solution, a discharge amount and a supply amount of the plating solution, and a standby time before the plating process for the substrate.

When the processing at step S13 ends or when the control section 77 determines at step S12 that the characteristics of the test patterns 10 are not in the abnormal range (No at step S12), the control section 77 controls the plating bath 71, the substrate retaining section 74, and the like to perform a plating process for forming a Cu film (step S14).

Thereafter, the control section 77 polishes the surface of the substrate with the CMP apparatus 60, removes the Cu film and the like deposited on the surface other than the wiring grooves, and forms wires (step S15). For example, when the third wiring layer 13 is formed by the plating process and the CMP, as shown in FIG. 5A, the stacked vias 22 and the wires 23 are formed in the third wiring layer 13.

The detecting sections 81₁ to 81ₙ of the detecting apparatus 80 pick up surface images of the stacked vias 22 formed in the semiconductor chip areas 2 and inspect whether the surfaces of the staked vias 22 are lost (step S16). For example, when the third wiring layer 13 is formed by the plating process and the CMP method, the detecting sections 81₁ to 81ₙ inspect whether the surfaces of the stacked vias 22 forming the test pattern 10a are lost (step S17).

When it is determined that the surfaces of the stacked vias 22 are lost (Yes at step S17), the control section 82 of the detecting apparatus 80 notifies the plating apparatus 70 of a result of the determination. The plating apparatus 70 adjusts the plating process conditions as at step S13 according to a state of loss of the stacked vias 22 (step S18). For example, when a defect is present in the stacked vias 22 of the test pattern 10a shown in FIG. 5A, the control section 82 adjusts plating process conditions of a plating process performed when the third wiring layer 13 of the next board is formed.

When the processing at step S18 ends or, for example, when it is determined that the surfaces of the stacked vias 22 are not lost (No at step S17), the control section 82 of the detecting apparatus 80 detects and notifies electric characteristics of the test patterns 10 (step S19).

Specifically, the control section 82 controls the detecting sections 81₁ to 81ₙ to acquire the electric resistances of the test patterns 10. The control section 82 discriminates, based on the electric resistances of the test patterns 10, the number and the distribution of defective chips, a fluctuation amount of the resistance between substrates, and the like.

The control section 82 notifies the plating apparatus 70, which performs the plating process in the preceding wiring step, of the electric resistances of the test patterns 10. For example, when the third wiring layer 13 is formed in the plating process at step S14, the control section 82 acquires an electric characteristic of the test pattern 10b and notifies the plating apparatus 70, which performs the plating process for the second wiring layer 12, of the electric characteristic of the test pattern 10b.

According to the embodiment, the test pattern 10 formed over three or more wiring layers and including the stacked vias 22 in an intermediate layer is formed in the semiconductor chip area 2. Conditions for the plating process are adjusted based on a characteristic of the test pattern 10. Because the stacked vias 22 has a high aspect ratio, the electric resistance of the test pattern sensitively fluctuates in response to deterioration in embedding properties and film formation characteristics of a plating film.

Therefore, it is possible to accurately detect embedded states and film formation states of Cu plating films with respect to the stacked vias 22 by detecting the electric resistance of the test pattern 10. It is possible to stabilize embedding properties and film formation characteristics of the Cu plating films by adjusting conditions for the plating process based on the detected embedded states and film formation states of the Cu plating films. For example, when the electric resistance of the test pattern 10 shows a tendency of increasing with time according to manufacturing of a semiconductor device, it is highly likely that plating embedding speed is deteriorated. An increase in electric current during the plating process, a reduction in rotation of the substrate, and an increase in flow rate of the plating solution are effective.

In the embodiment, the manufacturing apparatus 50 is caused to execute the various steps. However, the manufacturing apparatus 50 can include only the plating apparatus 70 and the detecting apparatus 80. The plating apparatus 70 and the detecting apparatus 80 can be provided for each wiring layer or can be provided in common to a plurality of wiring layers.

In the embodiment, the control section 82 of the detecting apparatus 80 discriminates the number and the distribution of defective chips, a fluctuation amount of resistance between substrates, and the like. However, the control section 77 of the plating apparatus 70 can perform the discrimination.

In the embodiment, the test patterns 10 are arranged in the semiconductor chip areas 2. However, the test patterns 10 are not limited to this arrangement. For example, the test patterns 10 can be arranged on one side near the outer periphery of the semiconductor chip area 2 or can be arranged to extend in one direction without being turned back in intermediate portions of the test patterns 10. The test patterns 10 can be formed on a dicing line of the semiconductor chip area 2.

In the embodiment, electric resistances are detected as electric characteristics of the test patterns 10. However, the capacitances of the test patterns 10 can be measured to adjust the conditions for the plating process.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A manufacturing method for a semiconductor device comprising:
forming a test pattern with a metal film embedded therein through a plating process;
detecting a characteristic of the test pattern; and
adjusting a condition for the plating process based on the detected characteristic of the test pattern, wherein
the test pattern is formed over three or more wiring layers and includes a stacked via in an intermediate layer.

2. The method according to claim 1, wherein
the forming the test pattern includes forming a plurality of the test patterns, and
the test patterns are respectively formed in intermediate layers having structures of the stacked via different from each other.

3. The method according to claim 1, wherein the test pattern is a pattern that meanders among the three or more wiring layers.

4. The method according to claim 1, wherein the test pattern is formed to surround an outer periphery of a device area where a semiconductor element is formed, and electrode pads are formed at both ends of the test pattern.

5. The method according to claim 4, wherein the test pattern is turned back in an intermediate portion, and the electrode pads at both the ends are arranged adjacent to each other.

6. The method according to claim 1, wherein the detecting a characteristic of the test pattern includes detecting, as the characteristic of the test pattern, at least one of electric resistance of the test pattern and a state of a surface of the stacked via.

7. The method according to claim 1, wherein the condition for the plating process includes at least one of a current value during plating film formation, temperature of a plating solution, a flow rate of the plating solution, a number of revolutions during the plating film formation of a substrate on which the test pattern is formed, and a standby time before a plating process for the substrate.

8. A manufacturing apparatus for a semiconductor device, comprising:
a detecting section configured to detect a characteristic of a test pattern formed with a metal film embedded therein through a plating process; and
an adjusting section configured to adjust a plating process condition in the plating process based on the characteristic of the test pattern detected by the detecting section, wherein
the test pattern is formed over three or more wiring layers and includes a stacked via in an intermediate layer.

9. The apparatus according to claim 8, wherein the detecting section detects, as the characteristic of the test pattern, at least one of electric resistance of the test pattern and a state of a surface of the stacked via.

10. The apparatus according to claim 8, wherein the condition for the plating process includes at least one of a current value during plating film formation, temperature of a plating solution, a flow rate of the plating solution, a number of revolutions during the plating film formation of a substrate on which the test pattern is formed, and a standby time before a plating process for the substrate.

11. The apparatus according to claim 8, wherein the test pattern is a pattern that meanders among the three or more wiring layers.

12. The apparatus according to claim 8, wherein the test pattern is formed to surround an outer periphery of a device area where a semiconductor element is formed, and electrode pads are formed at both ends of the test pattern.

13. The apparatus according to claim 12, wherein the test pattern is turned back in an intermediate portion, and the electrode pads at both the ends are arranged adjacent to each other.

14. The apparatus according to claim 8, further comprising a forming section configured to form a test pattern on a substrate with a metal film embedded therein through a plating process.

15. The apparatus according to claim 14, wherein
the forming section forms a plurality of the test patterns on the substrate, and
the test patterns are respectively formed in intermediate layers having structures of the stacked via different from each other.

16. A semiconductor device comprising a test pattern formed with a metal film embedded therein through a plating process, wherein
the test pattern is formed over three or more wiring layers and includes a stacked via in an intermediate layer.

17. The semiconductor device according to claim 16, wherein
the semiconductor device includes a plurality of the test patterns, and
the test patterns are respectively formed in intermediate layers having structures of the stacked via different from each other.

18. The semiconductor device according to claim 16, wherein the test pattern is a pattern that meanders among the three or more wiring layers.

19. The semiconductor device according to claim 16, wherein the test pattern is formed to surround an outer periphery of a device area where a semiconductor element is formed, and electrode pads are formed at both ends of the test pattern.

20. The semiconductor device according to claim 19, wherein the test pattern is turned back in an intermediate portion, and the electrode pads at both the ends are arranged adjacent to each other.
